(19) United States
(12) Patent Application Publication
(10) Pub. No.: US 2002/0131611 A1
(43) Pub. Date: Sep. 19, 2002

(54) `Audio surround sound power management switching

(76) Inventors: Alan Anderson Hoover, Indianapolis, IN (US); Mark Robert Anderson, Indianapolis, IN (US)

Correspondence Address: JOSEPH S. TRIPOLI, PATENT OPERATIONS, THOMSON multimedia Licensing Inc., CN 5312, PRINCETON, NJ, 08543-0028, US

(21) Appl. No.: 09/805,342

(22) Filed: Mar. 13, 2001

(51) Int. Cl. H04H 5/00; H03F 21/00; H02B 1/00

(52) U.S. Cl. 381/123; 381/120; 381/11

(57) ABSTRACT

An audio system has multiple amplifiers, each with power supply inputs and audio inputs and outputs, for driving audio speakers according to a selected one of at least two modes of operation in which a selection of the audio speakers and/or a required power output of the audio speakers differ between the modes. The invention is operable, for example, to an entertainment system that has internal and external speakers and associated amplifiers for switching between stereo and surround sound modes. At least two distinct power supply voltage sources are provided for the amplifiers, and a switching element operates upon switching between the modes to couple one or another of the distinct power supply voltage sources to the power supply inputs of respective ones of the at least two amplifiers. This the total audio output of the system from increasing, for example, when switching from two stereo outputs to five surround sound outputs.

The invention relates to an audio reproduction system. In particular, the invention relates to an audio system that is switchable between modes in which more or fewer audio amplifiers are selectively activated, for example, for switching between a stereo mode and a surround sound mode.

### BACKGROUND

Switching amplifiers between alternative supply voltages is known to be useful in some situations, and it is of course advantageous to switch off a supply voltage to elements that are unused, so as to avoid unnecessary power dissipation and heat. The SGS Thomson Microelectronics TDA 7294 Class G power amplifier, for example, is specified for dual bipolar supply voltages. Relatively lower magnitude positive and negative supply voltages are normally coupled to the power output stages of the amplifier. When the amplitude of the input voltage exceeds a threshold, higher magnitude supply voltages are switched in automatically, in place of the lower magnitude voltages. This accommodates the necessary swing in the output voltage of the amplifier without clipping, and reduces the average power dissipation of the amplifier because there is a lower voltage drop across the output transistors for a given output current at lower amplitudes, and less power consumption than would be the case at the higher magnitude supply voltages. Effectively, the TDA 7294 amplifier has two different power ratings, and automatically adjusts between the two ratings.

Home entertainment systems are known in which multiple audio outputs are provided to drive speakers that may have several modes of operation. A monaural audio signal requires one speaker; a stereo signal has two speakers that are usually spaced laterally and placed in front of the viewer or other audience; and, a surround-sound arrangement has at least a pair of speakers spaced laterally in front of the audience and a second pair spaced laterally behind the audience. The audio signals to these speakers are driven by signals that differ, sometimes in subtle ways, using combinations of channel separation, phasing and echo to provide a listening experience that can realistically mimic attendance of a performance in an auditorium or such other effect as desired by the program provider.

In order to be capable of presenting a surround sound signal, the entertainment system needs audio amplifiers and speakers for each of the speaker positions in the respective mode. Typically, there are at least five channels, amplifiers and speakers including a left-front, right-front, center-front, left-rear and right-rear.

Not all programming contains a surround sound signal. The user may choose to operate in a stereo mode or a monaural mode even if the programming is capable of stereo or surround sound, for example if the necessary speakers and wiring have not been installed. Preferably the system is switchable between these modes.

Usually, entertainment systems such as home-theater systems now available, at least have built-in stereo power amplifiers and speakers mounted in their cases. Systems capable of surround sound have additional built-in audio power amplifiers and connector couplings for driving external speakers. The amplifiers and speakers can support the external left-rear and right-rear surround speakers for use with the internal front speakers, or the user may choose instead to use external speakers to carry the left-front, right-front and center-front channel signals in addition to the necessarily external rear speakers. This requires a number of audio amplifiers.

Advantageously, menu selections or the like permit the user to configure the system to reflect the mode(s) of operation used. For example, the user may be permitted to disable the surround sound function if no rear speakers have been installed.

It is generally accepted in the audio art that for optimum system performance, the average power output of each active channel of a multi-channel system should be equal. If the audio output level applied to each channel or speaker is also equal, then switching from a mode using fewer channels and speakers to a mode using more channels and more speakers effectively multiplies the acoustic output power emitted into the room. Typically the user menu selections or other controls permit multiple axis volume and balance adjustments applicable to one or another of the modes of operation (e.g., left/right balance and front/rear fade). It is also possible that the amplitude of the input signals to the respective amplifiers can be switched automatically when changing modes.

There are several needs that are addressed by a system as described, including the capability of switching between modes using more or fewer speakers and the adjustment of the output volume when changing between modes. What such systems fail to provide, however, is an efficient technique for managing power dissipation when switching between modes. Conventional systems wastefully supply power to audio power amplifiers that may be wholly unused in certain modes of operation, and/or supply the same power supply and biasing levels to the amplifiers in each of the modes regardless of differences in the need for output power as a function of the selected mode. An inventive solution is provided for an audio system with multiple amplifiers, each with power supply inputs and audio inputs and outputs, for driving audio speakers according to a selected one of at least two modes of operation in which a selection of the audio speakers and/or a required power output of the audio speakers differ between the modes. The invention is operable, for example, to an entertainment system that has internal and external speakers and associated amplifiers for switching between stereo and surround sound modes. At least two distinct power supply voltage sources are provided for the amplifiers, and a switching element operates upon switching between the modes to couple one or another of the distinct power supply voltage sources to the power supply inputs of respective ones of the at least two amplifiers. Preferably, the switching element decouples all voltage sources from amplifiers that are unused in one or more modes. This reduces or eliminates power dissipation by the amplifiers, and effectively adjusts the output levels of the amplifiers so that the total audio output of the system is not multiplied, for example, when switching from two stereo outputs to five surround sound outputs. The invention can be switched or can respond to user selections or other reasons to accommodate a particular mode, and can be used to decouple power from amplifiers for unused internal or external speakers.

According to one inventive aspect, an audio system as described is provided with alternative power supply levels for the respective amplifiers used in the respective audio modes. By switching the input voltage to the amplifiers, the output amplitude of the respective channels is adjusted, thereby reducing or eliminating the need for supporting volume level adjustments specific to each mode. The system preferably has the same total audio output power in a stereo mode using internal speakers as in a stereo mode using external speakers, and also has the same total audio output power in a surround sound mode using five speakers. When switching to a mode that does not use a particular channel, this same amplifier power voltage switching technique eliminates power consumption by the power amplifiers of the de-selected channel(s).

### SUMMARY

An audio reproduction apparatus, embodying an aspect of the invention, includes a plurality of audio amplifiers, each being responsive to a corresponding audio signal for generating audio power in a corresponding audio speaker. A supply voltage is applied to a first audio amplifier of the audio amplifiers at a lower magnitude, in a first mode of operation, when audio power generated in a second audio amplifier of the audio amplifiers is higher. The supply voltage is at a higher magnitude, in a second mode of operation, when the audio power is generated in the second audio amplifier is lower, in a manner to reduce a change in a total audio power generated, when a change in the mode of operation occurs.

### IN THE FIGURES

FIG. 1 is a physical layout of an entertainment system or the like according to the invention, with multiple audio modes that selectively employ different combinations of audio speakers;

FIG. 2 is a schematic illustration of power supply switching arrangements according to an aspect of the invention; and

FIG. 3 is a detailed schematic diagram illustrating a practical embodiment of the invention as generally illustrated in FIG. 2.

### DETAILED DESCRIPTION

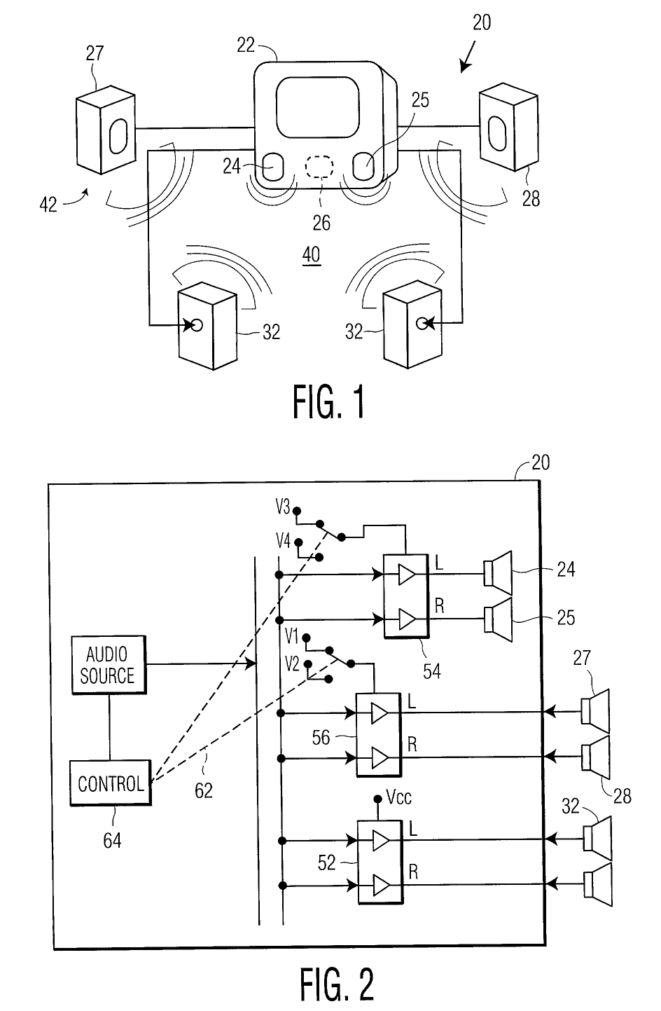

Referring to FIG. 1, an exemplary home entertainment system 20 is generally provided in a cabinet 22 having built-in audio speakers, such as a center speaker 26 and left and right stereo speakers 24, 25. The entertainment system 20 preferably includes the capacity to drive additional speakers 32, 42 external to cabinet 22. For a surround sound audio mode, the cabinet speakers 24, 25 (and optionally 26) are supplemented by rear speakers 32 to be disposed behind the area 40 usually occupied by the user or audience. Preferably the user has the option of likewise using external front speakers 27, 28 that either supplement or are used in lieu of the speakers 24, 25 provided in cabinet 22.

The speakers provided in the entertainment system are generally grouped by left versus right and front versus rear categories, and are subject to controls (not shown) that permit the speaker outputs to be balanced at the user's preference. Typically, a balance control varies the output level of the left speakers versus the right speakers. A fader control can similarly vary the output of the front speakers versus the rear speakers. In combination, the speakers can operate, for example, in a monaural mode using only the center speaker 26 or both left and right cabinet speakers 24, 25 together (or perhaps any group of speakers driven from the same signal), or in a stereo mode using one or more pairs of left and right speakers using separated channel signals.

In a preferred embodiment, monaural programming is routed to the left and right cabinet speakers 24, 25, which in that mode present the same signal. Stereo is presented using the left and right front external speakers 27, 28. In a surround sound mode, the speakers are nominally driven with five separated channel signals, namely right front, left front, center front, right rear and left rear, the latter two being routed to rear external speakers 32. In surround sound mode, the rear speakers 32 may be driven from additional separated left and right rear channel signals contained in the program received or being played back by entertainment system 20. Alternatively, the rear speakers 32 may be driven by signals that are the result of processing the separated left and right stereo signals that are coupled to the front speakers 27, 28. In that case, phasing and delay or echo effects may be included so as to provide the sensation of an audio source situated in the area of the front speakers 42, but presented in an auditorium or large space wherein acoustic paths would cause phasing and echo effects similar to those provided as a result of the processing.

All of the speakers are driven from the outputs of audio amplifiers 52, 54, 56, shown generally in FIG. 2. The audio amplifiers are likewise grouped in pairs, but each channel has a potentially separate signal and in that case requires a separate amplifier or channel. The amplifiers 52, 54, 56 preferably are power or output amplifiers that drive the speakers, although the invention also may be applied to controlling the amplitude of an amplifier stage that is placed upstream of the output amplifiers in a cascaded arrangement. Amplifiers 52, 54, 56 in the embodiment shown can be, for example, SGS Thomson Microelectronics model TDA7265 or equivalent. Audio power amplifiers often can be run on bipolar supply voltages, or they can be unipolar as in the embodiment shown in the drawings. To adapt the invention to a bipolar supply arrangement, the single-sided arrangement shown can be provided with substantially mirror image switching arrangements to change the supply voltages on both the negative and positive supplies when switched.

Gain controls (not shown) are provided in known manner for volume, balance and fade, and enable the user to set a volume level and to balance the relative volume levels laterally and from front to rear. The gain controls can include manually operated control elements such as potentiometers or the like, or can be associated with a system controller, shown generally as an audio source, that adjusts the levels in response to user selections made in a menu technique via an infrared remote control signaling unit or the like, and routes the required signals to the required amplifiers by a switching matrix that in FIG. 2 is represented generally by a signal bus. Such user selections can also be the basis for generation of the signal that switches the circuit of the invention between its stereo and surround sound modes.

According to the invention, the audio system has at least amplifiers 52, 54, 56 that each have a power supply input. In the embodiment shown, the left and right amplifiers are in pairs (surround pair, front pair, rear pair) having a single power supply input to each dual amplifier package. Each channel of each of the pairs (i.e., each amplifier) has an audio signal input and audio signal output for driving a speaker. The amplifiers for the speakers 24, 25 permanently mounted in the cabinet (the “internal” speakers) are directly coupled to the respective audio signals as shown in FIG. 2. The remaining amplifiers 54, 56 in the embodiment shown are separately coupleable to external speakers 27, 28, 32 by suitable connectors. The amplifiers 52, 54, 56 drive their associated audio speakers to provide an audio power output level that is a function of the gain of each amplifier and the amplitude of the input signal coupled to the amplifier.

The audio system has at least two modes of operation in which one or both of the selection of which audio speakers are to be operational, and the selection of the required power output of the audio speakers, differ between the modes. The required power output of the amplifiers, and thus of the audio speakers is in part a function of the supply voltage coupled to the amplifiers.

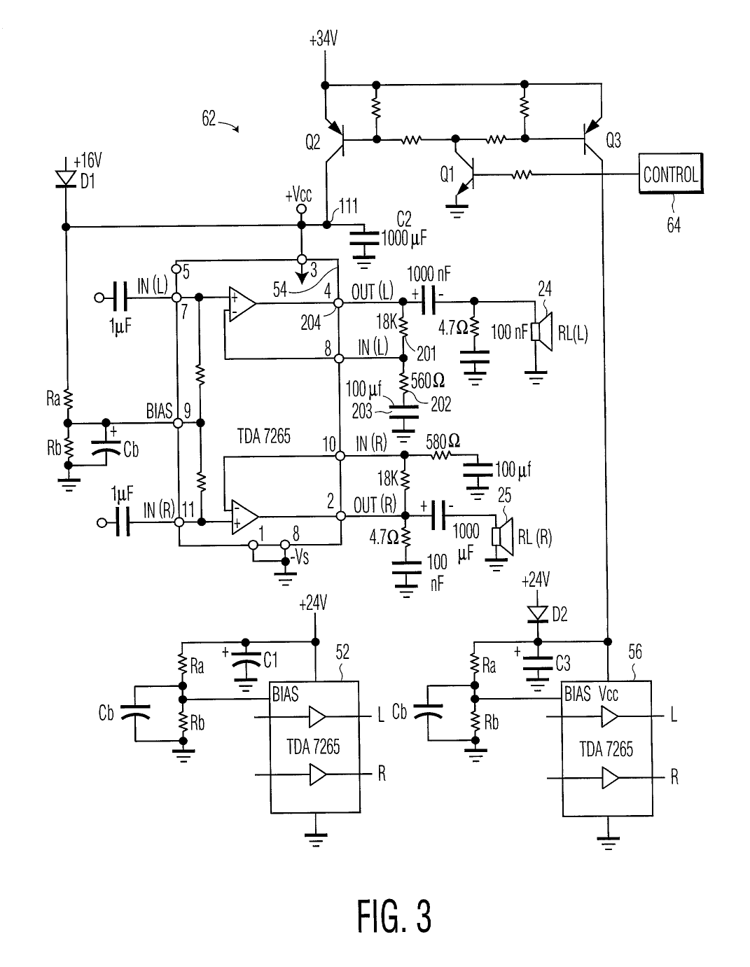

According to an inventive aspect, at least two distinct power supply voltage sources are provided for at least certain of the amplifiers. In the embodiment shown, the power supply voltage to a surround sound amplifier package 52 for driving the external rear speakers, is set and unchangeable at a predetermined voltage Vcc. This voltage preferably is only applied in the surround sound mode and is not applied in other modes or if the entire unit is turned off and unpowered. The voltages applied to the amplifier 54 for the internal or main left and right speakers (the cabinet speakers) and the voltages applied to the amplifier 56 for the external front left and right speakers, are changeable. Specifically, two different supply voltages V1 or V2, and V3 or V4, respectively, are provided and at least one switching element 62 is operable responsive to a control 64 upon switching between the modes to couple one of the distinct power supply voltage sources to the power supply inputs of the respective amplifier or pair of amplifiers. The switching element 62 can be operable in at least one of the modes of the system to decouple all voltage sources from at least one of the amplifiers, thereby eliminating power dissipation by that amplifier. According to an alternative embodiment, more and fewer amplifiers and speakers can be activated in at least two modes and perhaps additional modes. FIG. 3 illustrates the audio amplifiers and their switched power supply arrangements of the entertainment system 20 and power supply—amplifier—speaker arrangements shown in FIGS. 1 and 2. Similar symbols and numerals in FIGS. 1, 2 and 3 indicate similar items or functions.

According to the exemplary embodiment shown in FIGS. 2 and 3, the modes comprise monaural, stereo and surround sound modes of operation. The modes can optionally include one or more modes entered by a setup procedure in which the user selects an option from a menu indicating that no external speakers are coupled to one or the other of the external speaker inputs, in which event the voltage supply to the corresponding amplifier can be switched off. That mode may be useful, for example, to permit the user to choose at his option to employ the surround sound mode but to do so using the internal (cabinet) main left and right speakers 24, 25 (and perhaps a center cabinet speaker 26), for the front speakers used, and external speakers 32 for the rear speakers.

The switching element or elements are operable to couple the amplifiers to lower power supply voltages in at least one such mode in which relatively more amplifiers and speakers are used, such as a surround sound mode, and to couple at least one of the amplifiers to a higher power supply voltage in at least one other mode that uses relatively fewer amplifiers and speakers. This has the effect or reducing the per-speaker audio power output in the mode that employs relatively more amplifiers and speakers at lower supply voltage.

In carrying out an inventive feature, lowering the per speaker power output in this manner can be used to activate and use relatively more speakers, for example in a more dispersed array, without increasing substantially the total power output from all the speakers that are used. Voltages V1, V2, V3, V4 and Vcc may be produced from a single power supply, not shown, having a fixed maximum power rating. By providing lower voltage levels, when more speakers and amplifiers are energized and higher voltage levels, when fewer speakers and amplifiers are energized, the same fixed maximum power rating can be, advantageously, maintained.

For example, when switching from using two speakers to four speakers, and assuming that the original two speakers are among the four speakers to be used, the switching element couples a lower supply voltages to the amplifiers that drive the original two speakers. The switching element optionally can couple or decouple a supply voltage to the amplifiers for the other two speakers to be used, in order to power those amplifiers when they had not previously been powered in the other mode of operation. Alternatively, those added speakers can be coupled to an amplifier that is always powered, but an active signal is only applied in the mode having the added two speakers. In that event, the added speakers' amplifier should be chosen so as to dissipate minimal power unless its input signal is active.

The supply voltages to the two original amplifiers are changed when those amplifiers are to be used to power members of a different number of speakers (reduced when switching from a smaller number to a larger number of active channels, or vice versa). In this way, the total audio power output of the speakers in the smaller group can be approximately the same as the total audio power output of the speakers in the larger group, each of which is less forcefully driven. This arrangement conserves power compared to a similar arrangement in which the powers supply voltage to the original speakers is not reduced. The power supply savings accrue even if the amplitude of the input signals to the switched-supply amplifiers is adjusted so as to use the signal amplitude as a means to adjust the volume of the audio output, because there is a smaller voltage drop at least across the output or driver stage of the amplifier, and less power dissipation. As indicated before, by providing lower voltage levels, when more speakers and amplifiers are energized and higher voltage levels, when fewer speakers and amplifiers are energized, the same fixed maximum power rating can be, advantageously, maintained. Therefore, there is no need to provide a power supply with a higher power rating in each of the modes of operation.

A preferred application of the invention is switching from a stereo mode to a surround sound mode, but the same technique could apply to other situations in which a change is made in the number of speakers and amplifiers that are actively employed. In the preferred application the audio system has a main two channel amplifier and associated speakers, and an external two channel amplifier having an audio output coupleable to external speakers. Another application is to an audio system having a main two channel amplifier with an audio output coupleable to front stereo speakers and a surround two channel amplifier having an audio output coupleable to rear stereo speakers. The audio system optionally can have a center channel speaker driven by at least a selectable one of the amplifiers. Typically, the center channel is used to drive both cabinet speakers monaurally in surround sound mode and the front and rear surround sound signals are directed to the front and rear pairs of external speakers.

The audio system 20 as shown in FIG. 1 can be a television chassis home entertainment system, containing three stereo audio power amplifiers as shown in FIGS. 2 and 3, which support different configurations. In a first or internal stereo mode, a 12.5 watt per channel stereo amplifier 54 (i.e., two channel amplifier) is coupled to drive two self contained or cabinet speakers 24, 25. Additionally, a 12.5 watt per channel stereo amplifier 56 is provided for coupling, at the user's choice, to two external speakers 27, 28 that are to be used as front speakers (see also FIG. 1). Use of the external speakers can provide a second mode of operation (an external stereo mode) that is comparable to the main internal stereo mode, if the internal speakers are disabled when the external speakers are used. Otherwise, if the user chooses to use the cabinet speakers and the external front speakers at the same time, then the total audio power level might be doubled because two stereo amplifiers would power four speakers, whereas in the internal mode there was one stereo amplifier of the same rated wattage, driving the two cabinet speakers.

A third mode of operation is a five channel surround mode. In this mode, the two internal speakers 24, 25 can carry the center front channel signal. The front external speakers 27, 28 carry the front left and right signals. A third amplifier 52 powers the left and right rear surround speakers 32.

Preferably, the user may choose by appropriate menu selections, switch inputs or the like, to operate in surround mode or in stereo mode or in various combinations of internal and external speaker use. Such a choice might be advantageous even if signals are available for driving the rear speakers 32, either in the program being presented or as a processed version of the front speaker signals. For example, the user may not have wired the system to support surround sound, or if already wired may simply choose to use the system in a less imposing manner than would be possible using all its capabilities.

In a full five channel surround sound mode, taking advantage of front and rear external speakers, and using the two internal (cabinet) speakers 24, 25 for the center speaker signal, it would be possible to power the main internal stereo amplifier 54 and the external front speaker amplifier 56 by their 12.5 watt per channel stereo amplifiers discussed above, using the same nominal supply voltage to power both amplifiers. If the third stereo amplifier 52 was of the same 12.5 watt rated power and was also driven from the nominal supply voltage to power the rear surround speakers, changing from stereo to surround sound modes would increase the acoustic power output by a factor of three. The relative power level of the center channel would be twice the level of any other single channel. This would likely require adjustment of the audio levels. Even assuming an automatic adjustment, the power supply would be effectively over designed for the application.

According to the present inventive approach to this problem, power supply levels to the amplifiers are switched between alternative higher and lower voltages to adjust the relative power outputs of the channels and to reduce power dissipation. As shown in FIG. 3, this can be accomplished so as to have the same total audio output power and the same total power requirement from the power supply in the stereo mode as in the surround mode. Furthermore, according to the inventive solution, the power output per channel can be made equal in the surround sound mode for all five channels, and the capacity of the power supply is fully used in both modes.

The main stereo amplifier 54 of FIG. 3 (i.e., the internal or cabinet speaker amplifier) is supplied with +34 volts dc, through a saturated bipolar transistor switch Q2. Switch Q2 is conductive or “on” in the stereo mode only, and in that mode couples the +34 volts dc supply voltage, but for a base-emitter voltage drop, to a power supply terminal 111 of the main stereo amplifier 54. Switch Q2 is switched into the stereo mode by an output of a system control network of switching elements 62. The control element can be associated with an audio source that is capable of switching between the stereo and other modes. Preferably the output of the control element is settable at the user's option in association with pre-selecting stereo operation.

Another supply voltage at +16 volts dc is coupled to the power supply terminal of main stereo amplifier 54 through diode D1. Thus diode D1 is reverse biased in the stereo mode and blocks conduction from the +34 volt supply to the +16 volt supply.

In the stereo mode, the main stereo amplifier 54 supplies 12.5 watts of audio power per channel to each of the two cabinet mounted internal 8 ohm speakers 24, 25, due to the presence of the +34 volt supply. The total power output in this stereo mode is 25 watts.

In the surround sound mode, switch Q2 is switched off, decoupling the +34 volt supply from the main stereo amplifier. Diode D1 becomes forward biased and supplies +16 volts to the main stereo amplifier, less a diode drop. At this supply voltage, the main stereo amplifier 54 supplies only 2.5 watts per channel or a total of 5 watts. In this mode, the signal input to both parallel amplifiers in the main stereo amplifier 54 preferably is the same monaural signal, namely the center channel signal in the surround sound mode from the audio source.

The external stereo amplifier 56 is supplied +34 volts through another saturated bipolar transistor switch Q3. Another blocking diode D2 is similarly coupled to an additional dc supply at +24 volts. When switch Q3 is on (in stereo mode only), +34 volts is applied to the external stereo amplifier 56, less the base-emitter drop of transistor switch Q3 in saturation. Diode D2 is reverse biased, which prevents conduction from the +34 volt supply to the +24 volt supply. The external stereo amplifier 56 supplies 12.5 watts per channel to each external 8 ohm speaker for a total of 25 watts output power in the stereo mode.

Transistor switch Q3 is switched off in the surround sound mode. The +34 volt supply cannot conduct current to the external stereo amplifier. Diode D2 becomes forward biased and supplies +24 volts to the voltage supply terminal of the external stereo amplifier 56, which at that supply voltage can supply 5 watts to each channel or a total of 10 watts.

The third amplifier, namely surround amplifier 52, is supplied +24 volts in this embodiment, which is not switched between voltage levels when changing between modes. The voltage can optionally be switched on and off by additional switch means (not shown), but this amplifier 52 is used only in surround sound mode and need not be switched to accommodate different power levels as is the case with the main and external stereo amplifiers 54, 56. At the noted supply voltage of 24 volts, the surround amplifier 52 produces 5 watts per channel, namely for the left and right rear or surround speakers.

According to the foregoing embodiment, the total output power of the amplifiers operating in the foregoing modes is 25 watts. Inasmuch as the power supply voltages are reduced when relatively more amplifier channels and speakers are active, and increased when fewer channels and speakers are active, the invention provides an efficient output level control that also prevents undue power dissipation. Whether the system is in the two channel stereo mode or the five channel surround sound mode, the power supply is fully utilized, and the output power levels in both these modes are the same.

In addition to the basic power supply switching arrangements as discussed, the embodiment of the invention shown in FIG. 3 comprises filter capacitors C1, C2 and C3 coupled between the supply voltage terminals of each dual amplifier package 52, 54, 56 and ground for decoupling the amplifiers from variations in the power supply voltage. Additionally, each of the supply voltage inputs to the amplifiers are coupled to a voltage divider to ground, defined by resistors Ra, Rb. The junction of resistors Ra, Rb is coupled to the amplifier bias input, and resistor Rb is coupled in parallel with a capacitor Cb, namely between the bias input and ground. When changing from a lower supply voltage to a higher supply voltage, capacitor Cb charges through resistor Ra, bringing the bias input voltage up smoothly to a reference value equal to one-half of the supply voltage, defined by the voltage divider.

Each of dual amplifier package 52, 54 and 56 includes a pair of audio amplifiers, for example, a non-inverting amplifier 54a of amplifier package 54.The gain of amplifier 54a is established by a pair of feedback resistors 201 and 202 in a conventional manner. Resistor 202 is AC-coupled to ground via a capacitor 202. A half supply voltage developed at input terminal Bias is DC coupled to a non-inverting input terminal of amplifier 54a. Because resistor 202 is not DC-coupled to ground, the DC gain of amplifier 54a is unity. The result is that a DC component voltage at an output terminal 204 is equal to one half the supply voltage developed at input terminal Bias. Thereby, a single ended power supply is used for producing an output voltage at terminal 204 having the DC component voltage that is equal to one half the supply voltage.

The respective switching elements, including transistors Q1, Q2, Q3 are off in surround sound mode and on in the stereo mode, and control voltage switching. The switching elements are responsive to a status output of the controller which may be generated as a function of user selection of stereo versus surround sound operation. In addition to the switching elements shown for purpose of illustration, additional switching elements (not shown) can be used, for example, to disable one or another of the modes or amplifiers according to user selections and other factors, for example to permit combinations of internal and external speakers other than the standard combinations described above. For some surround program source types, such as Dolby Pro Logic surround, there is nothing inherent in the program material that would give a unique signature, in which event the selection can be made at the option of the user. On the other hand, a digital source such as AC-3 has this capability of carrying a signal representing the mode in which the audio signal is encoded, which could be used to switch automatically between the stereo and surround sound modes.

What is claimed is:

1. An audio reproduction apparatus, comprising:
a plurality of audio amplifiers, each being responsive to a corresponding audio signal for generating audio power in a corresponding audio speaker; and
means for selectively applying a supply voltage to a first audio amplifier of said audio amplifiers at a lower magnitude, in a first mode of operation, when audio power generated in a second audio amplifier of said audio amplifiers is higher, and at a higher magnitude, in a second mode of operation, when the audio power generated in said second audio amplifier is lower, in a manner to reduce a change in a total audio power generated, when a change in the mode of operation occurs.

2. The audio reproduction apparatus according to claim 1, further comprising means for selectively enabling audio power generation in said second audio amplifier, in said first mode of operation, and for disabling the audio power generation in said second audio amplifier, in said second mode of operation.

3. The audio reproduction apparatus according to claim 2, wherein the generation of the audio power in said second audio amplifier is enabled in a surround sound mode of operation and disabled in at least one of a monaural mode of operation and a stereo mode of operation.

4. The audio reproduction apparatus according to claim 3, wherein the generation of the audio power in said first audio amplifier is enabled both in said surround sound mode of operation and in said at least one of said monaural and stereo modes of operation.

5. The audio reproduction apparatus according to claim 1, wherein said supply voltage applying means comprises a switch for selectively coupling a source of a first supply voltage to a power supply input of said first audio amplifier, in said first mode of operation, and a source of a second supply voltage, in said second mode of operation.

6. The audio reproduction apparatus according to claim 1, wherein both said first and second audio amplifiers are energized from a common power supply having a power rating that is determined by the total audio power produced in each of said first and second audio amplifiers.

7. A method for reproducing audio, comprising:
providing a plurality of audio amplifiers, each being responsive to a corresponding audio signal for generating audio power in a corresponding audio speaker; and
selectively applying a supply voltage to a first audio amplifier of said audio amplifiers at a lower magnitude, in a first mode of operation, when audio power generated in a second audio amplifier of said audio amplifiers is higher, and at a higher magnitude, in a second mode of operation, when the audio power generated in said second audio amplifier is lower, in a manner to reduce a change in a total audio power generated, when a change in the mode of operation occurs.

8. The method according to claim 7, further comprising the steps of selectively enabling audio power generation in said second audio amplifier, in said first mode of operation, and disabling the audio power generation in said second audio amplifier, in said second mode of operation.

9. The method according to claim 8, further comprising the steps of enabling the generation of the audio power in said second audio amplifier in a surround sound mode of operation and disabling the generation of the audio power in said second audio amplifier in at least one of a monaural mode of operation and a stereo mode of operation.
